(19) United States
(12) Patent Application Publication
(10) Pub. No.: US 2013/0319510 A1
(43) Pub. Date: Dec. 5, 2013

(54) FLUOROPOLYMER-BASED FILM FOR PHOTOVOLTAIC APPLICATION

(71) Applicants: Anthony Bonnet, Saint Laurent de Mure (FR); Nicolas Devaux, Lyon (FR); Barbara Ramfel, Barc (FR); Emmanuel Veret, Serquigny (FR); Stephane Bizet, Barc (FR); Gregory S. O'Brien, Downingtown, PA (US)

(72) Inventors: Anthony Bonnet, Saint Laurent de Mure (FR); Nicolas Devaux, Lyon (FR); Barbara Ramfel, Barc (FR); Emmanuel Veret, Serquigny (FR); Stephane Bizet, Barc (FR); Gregory S. O'Brien, Downingtown, PA (US)

(73) Assignee: Arkema France, Colombes (FR)

(21) Appl. No.: 13/879,138

(22) PCT Filed: Sep. 30, 2011
(86) PCT No.: PCT/FR2011/052287

§ 371 Date: Jul. 2, 2013

(30) Foreign Application Priority Data
Oct. 13, 2010 (FR) 1058328

(51) Int. Cl. H01L 31/048; B29C 49/00; B29C 39/00; B29C 49/04; B29C 47/00

(52) U.S. Cl. CPC H01L 31/0487; B29C 49/04; B29C 47/0004; B29C 39/003; B29C 49/0005
USPC 136/251; 428/220; 264/555; 264/212; 264/299; 524/432

(57) ABSTRACT

The present invention relates to a composition comprising a fluoropolymer and two white inorganic fillers, the said composition being intended for the manufacture of thin monolayer films which are opaque to visible light and to UV rays and which can be used in particular in the field of photovoltaic cells. This composition consists of at least one fluoropolymer and of two white inorganic fillers, which are zinc oxide and titanium oxide; they are present in a proportion by weight ranging from 5 to 30% and from 3 to 7.5% respectively, The said composition additionally comprises less than 5% by weight of acrylic polymer, with respect to the total weight of the composition.

The present invention relates to a composition comprising a fluoropolymer and two white inorganic, fillers, the said composition being intended for the manufacture of thin monolayer films, opaque to visible light and to UV radiation, which can be used in particular in the field of photovoltaic cells.

It is essential, in a photovoltaic cell, to protect the constituent components against environmental factors. Thus, the back part of the cell has to be protected by a polymer film in order to prevent it from being damaged by ultraviolet (UV) rays and to prevent moisture from penetrating. The protective film must have bulk or dimensional thermal stability in order to avoid thermal expansion and in particular shrinkage during the assembling of the cells. The photovoltaic cells are assembled by bonding the various layers using a solvent-based adhesive, followed by lamination. The use of solvents in adhesives may bring about penetration of these solvents into the film. The cells are assembled at high temperature (>130° C.) and optionally using a surface oxidation treatment of corona type. When the protective film is based on fluoropolymer, this treatment can result in yellowing and in a deterioration in the mechanical properties of the latter.

Furthermore, it is known to use fluoropolymers in general and in particular PVDF (polyvinylidene difluoride) to manufacture films intended to protect objects and materials, due to their very good resistance to bad weather, to UV radiation and to visible light, and to chemicals. However, it is necessary for these films to exhibit a very good thermal resistance for exterior applications subject to severe climatic conditions (rain, cold, heat) or conversion processes carried out at high temperature (greater than 130° C.). It is also necessary for the films to exhibit good flexibility and good tensile strength, so as to withstand the mechanical stresses during the positioning thereof on the object or the material to be covered.

Generally, in order to protect a polymer film from damage by UV rays, UV absorbers and/or inorganic fillers are incorporated therein. It is known that the addition of inorganic fillers, such as TiO₂, SiO₂, CaO, MgO, CaCO₃, Al₂O₃ and a great many others still, to a fluoropolymer, such as a vinylidene fluoride polymer or copolymer (PVDF), can result in fairly serious damage with production of hydrogen fluoride (HF) when the blending is carried out in the molten state at high temperature in order to disperse the filler. One route for processing these fillers with, for example, PVDF consists in introducing these inorganic fillers using an acrylic masterbatch. To this end, the inorganic fillers are dispersed in a methyl methacrylate polymer or copolymer (PMMA) and then this masterbatch is blended with the PVDF in the molten state. The presence of a PMMA results in disadvantages, such as a limitation on the dimensional stability of the film obtained with regard to temperature, a lower thermal resistance, an odour characteristic of the acrylic during the assembling of the cells and a lower stability to UV radiation in comparison with a pure PVDF. Such a film comprising a tripartite fluoropolymer/acrylic polymer/inorganic filler composition is described, for example, in the document WO 2009/101343. The proportion of acrylic polymer varies from 5 to 45 parts per 100 parts of composition.

The Applicant Company has described, in Application FR 1 050 226, compositions based on fluoropolymers and comprising just one inorganic filler which make it possible to prepare films opaque to UV and visible radiation while retaining very good properties of dimensional stability at the temperatures used for the manufacture of a backsheet and subsequently of a photovoltaic panel. These compositions comprise a fluoropolymer and zinc oxide (ZnO), the said filler being present in the said composition in a proportion by weight of 5 to 50%. The use of this filler makes it possible, on the one hand, to avoid the addition of acrylic polymers to the fluoropolymer and, on the other hand, to use processing temperatures compatible with the manufacture by blown film extrusion of a monolayer film, namely of the order of 220 to 260° C., which makes it possible to avoid damage to the fluoropolymer. The use of zinc oxide makes it possible to obtain a film which is opaque to ultraviolet and visible radiation at a thickness of 20 μm. It has been found that the use of zinc oxide as sole white inorganic filler does not make it possible to obtain a transmission of less than 30% at wavelengths of the visible region, for fine layers with a thickness of less than 20 μm. In point of fact, some applications, in particular in the field of photovoltaic modules, require film thicknesses of less than 20 μm.

The present invention thus intends to provide fluoropolymeric compositions which make possible the manufacture of thin films (less than 20 μm) which are opaque to UV and visible radiation and which comprise little or nothing in the way of acrylic polymers.

To this end, the invention relates, according to a first aspect, to a composition consisting of at least one fluoropolymer and of two white inorganic fillers, characterized in that the said fillers are zinc oxide and titanium oxide, in that they are present in a proportion by weight ranging from 5 to 30% and from 3 to 7.5% respectively (limits included) and in that the said composition additionally comprises up to 5% by weight of acrylic polymer, these percentages being calculated with respect to the total weight of the composition. The content by weight of acrylic polymer is thus greater than 0% and less than 5%, with respect to the total weight of the composition.

The invention also relates to the process for producing the said formulation, to the film obtained from this formulation and to its use in the photovoltaic field as protective film for a PET substrate used as back protection for photovoltaic panels. More particularly, the invention relates to a photovoltaic cell, the back panel of which is coated with a film as described above. According to yet another aspect, the invention relates to the various processes for the manufacture of the abovementioned monolayer film.

The invention will now be described in detail:

According to a first aspect, the invention relates to a polymeric composition comprising at least one fluoropolymer and two pigments based on zinc and titanium, the simultaneous presence of which makes it possible to obtain, for the thin films manufactured from the said composition, an opaqueness to UV radiation up to a wavelength of 395 nm, while having a very good opaqueness in the visible region with a transparency of less than 25% at 450 nm, with excellent thermal stability and a yellowing index (YI) of less than 4. This combination of properties is obtained, on the one hand, by virtue of the presence of two white inorganic fillers, namely zinc oxide and titanium dioxide, and, on the other hand, by virtue of the limitation of the content of acrylic polymers to less than 5% by weight, with respect to the total weight of the composition.

As regards the fluoropolyrner, the latter is prepared by polymerization of one or more monomer(s) of formula (I):

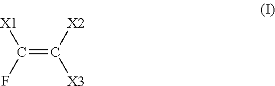

in which:
X1 denotes H or F;
X2 and X3 denote H, F, Cl, a fluoroalkyl group of formula CₙFₘHₚ— or a fluoroalkoxy group CₙFₘHₚO, a being an integer between 1 and 10, m being an integer between 1 and (2n+1) and p having the value 2n+l-m.

Use may be made, as monomers, of: hexafluoropropylene (HFP), tetrafluoroethylene (TFE), vinylidene fluoride (VDF, CH₂═CF₂), chlorotrifluoroethylene (CTFE), perfluoroalkyl vinyl ethers, such as CF₃—O—CF═CF₂, CF₃—CF₂—O—CF═CF₂ or CF₃—CF₂CF₂—O—CF═CF₂, 1-hydropentafluoropropene, 2-hydropentafluoropropene, dichlorodifluoroethylene, trifluoroethylene (VF₃), 1,1-dichlorofluoroethylene and their mixtures, or fluorine-comprising diolefins, for example diolefins such as perfluorodiallyl ether and perfluoro-1,3-butadiene.

The fluoropolymers which may participate in the composition according to the invention are chosen from:
TFE homo- or copolymers, in particular PTFE (polytetrafluoroethylene), ETFE (ethylene/tetrafluoroethylene copolymer) and TFE/PMVE (tetrafluoroethylenel-perfluoro(methyl vinyl)ether copolymer), TEE/PEVE (tetrafluoroethylene/perfluoro(ethyl vinyl) ether copolymer), TFE/PPVE (tetrafluoroethylene/perfluoro(propyl vinyl) ether copolymer) and E/TFE/HFP (ethylene/tetrafluoroethylene/hexafluoropropylene terpolymers)copolymers;
VDF homo- or copolymers, in particular PVDF and VDF/HFP copolymers;
CTFE homo- or copolymers, in particular PCTFE (polychlorotrifluoroethylene) and E/CTFE (ethytene/chlorotrifluoroethylene copolymer).

Preferably, the fluoropolymer is a VDF homopolymer or a copolymer of VDF and of at least one other fluoromonomer.

Advantageously, the fluorocomonomer which can copolymerize with the VDF is chosen, for example, from vinyl fluoride, trifluoroethylene (VF3); chlorotrifluoroethylene (CTFE); 1,2-difluoroethylene; tetrafluoroethylene (TFE); hexafluoropropylene (HFP); perfluoro(alkyl vinyl)ethers, such as perfluoro(methyl vinyl)ether (PMVE), perfluoro(ethyl vinyl)ether (PEVE) and perfluoro(propyl vinyl)ether (PPVE); perfluoro(1,3-dioxole); perfluoro(2,2-dimethyl-1,3-dioxole) (PDD), and their mixtures.

Preferably, the fluorocomonomer is chosen from chlorotrifluomethylene (CTFE), hexafluoropropylene (HFP), trifluoroethylene (VF3) and tetrafluoroethylene (TFE), and their mixtures. The comonomer is advantageously HFP as it copolymerizes well with VDF and makes it possible to contribute good thermomechanical properties. Preferably, the copolymer comprises only VDF and HFP.

Preferably, the fluoropolymer is a VDF homopolymer (PVDF) or a VDF copolymer, such as VDF/HFP, comprising at least 50% by weight of VDF, advantageously at least 75% by weight of VDF and preferably at least 90% by weight of VDF. Mention may be made, for example, more particularly of the following VDF homopolymers or copolymers comprising more than 75% of VDF and the remainder of HFP: Kynar® 710, Kynar® 720, Kynar® 740, Kynar Flex® 2850 and Kynar Flex® 3120, sold by Arkema. Advantageously, the composition according to the invention comprises two distinct fluoropolymers, at least one of which is a VDF homopolymer.

Advantageously, the fluoropolymer has a viscosity ranging from 100 Pa·s to 3000 Pa·s, the viscosity being measured at 230° C. at a shear gradient of 100 s⁻¹ using a capillary rheometer. This is because this type of polymer is well suited to extrusion. Preferably, the polymer has a viscosity ranging from 500 Pa·s to 2900 Pa·s.

The first white inorganic filler is zinc oxide (ZnO). It has an opacifying role in the UV/visible region and acts as sunscreen, so that the film prepared from the composition according to the invention is a film which is opaque to UV radiation, mainly by scattering/reflection of the UV rays, but also to visible light.

The ZnO content of the composition is between 5 and 30% by weight, advantageously between 10 and 20% by weight (limits included), with respect to the total weight of the composition.

The second white inorganic filler is titanium dioxide (TiO₂), Like zinc oxide, titanium oxide has an opacifying role in the UV/visible region and acts as sunscreen, so that the film prepared from the composition according to the invention is a film which is opaque to UV radiation, mainly by scattering/reflection of the UV rays, but also to visible light.

The TiO₂ content of the composition is between 3 and 7.5% by weight, advantageously between 3 and 6% by weight (limits included), with respect to the total weight of the composition.

The acrylic polymer (or acrylate) is a methyl methacrylate (MMA) homopolymer or a copolymer comprising at least 50% by weight of MMA and at least one other monomer which can copolymerize with MMA. Comonomers which can copolymerize with MMA are alkyl(meth)acrylates, acrylonitrile, butadiene, styrene or isoprene.

Advantageously, the acrylic polymer (MMA homopolymer or copolymer) comprises, by weight, from 0 to 20% and preferably from 5 to 15% of a C₁-C₈ alkyl (meth)acrylate, which is preferably methyl acrylate and/or ethyl acrylate. The acrylic polymer can be functionalized, that is to say that it comprises, for example, acid, acid chloride, alcohol or anhydride functional groups. Advantageously, the functionality is in particular the acid functional group introduced by the acrylic acid comonomer. Use may also be made of a monomer comprising two neighbouring acrylic acid functional groups which can dehydrate to form an anhydride. The proportion of functionality can be from 0 to 15% by weight of the MMA polymer.

The invention also relates to a process for the manufacture of the said composition which comprises several stages. In a first step, a first masterbatch comprising the zinc oxide (known as “masterbatch A”) is prepared by incorporation by the molten route of ZnO in a fluoropolymer, the viscosity of which is less than 1000 Pa·s at 230° C. for a shearing of 100 s⁻¹. This makes it possible to obtain a good state of dispersion of the zinc oxide particles in the fluoropolymer. Separately, a second masterbatch (known as “masterbatch B”), which is an acrylic masterbatch, is prepared by incorporation by the molten route of TiO₂ in an acrylic matrix, The TiO₂ content of this masterbatch B must be greater than 50% by weight in order to keep the level of final acrylic polymer below 5%.

The masterbatch A is subsequently dispersed in a more viscous fluorinated matrix which makes it possible to obtain good mechanical properties, before and after thermal ageing. The masterbatch B is added to this mixture. The product thus obtained is subsequently extruded, so as to produce the thin films according to the invention.

According to another aspect, a subject-matter of the invention is a monolayer film manufactured from the composition described above. This film is opaque to UV and visible radiation while retaining very good properties of dimensional stability at the temperatures used for the manufacture of a backsheet and subsequently of a photovoltaic panel.

The film according to the invention exhibits the following characteristics:
a thickness of less than 20 μm, preferably of between 15 and 19 μm and advantageously of between 16 and 18 μm (limits included);
a density of between 1.98 and 2.07 g/cm³ (limits included);
a weight per unit area of between 29.7 and 41.4 g/m² (limits included);
an elongation at break (in %):
   in the machine direction: of between 200 and 300;
   in the cross direction: of between 180 and 270;
a tensile strength (in MPa):
   in the machine direction: of between 20 and 70;
   in the cross direction: of between 10 and 60;
a dimensional modification after passing to the oven at 150° C. for 30 mm (in %):
   in the machine direction: less than or equal to 0.5;
   in the cross direction: less than or equal to 0.5.

This film is opaque to UV and visible radiation and exhibits a long-term stability, as shown by the damp heat test at 85° C. and 85% humidity for 2000 h and by the UV ageing test.

Advantageously, the film according to the invention does not exhibit an acrylic odour.

The film according to the invention can be manufactured by blown film extrusion at a temperature ranging from 220 to 260° C. This technique consists in coextruding, generally from the bottom upwards, a thermoplastic polymer through an annular die. The extrudate is simultaneously drawn longitudinally by a drawing device, usually in the form of rolls, and inflated with a constant volume of air trapped between the die, the drawing system and the wall of the tube. The inflated tube is generally cooled by an air blowing ring at the die outlet.

Advantageously, the nature of the first white inorganic filler (ZnO) and the presentation of the second white inorganic filler (TiO₂) in an acrylic matrix make it possible to obtain the film by the blown film extrusion technique at temperatures of 220-260° C. without causing damage to the fluoropolymer present in the said composition. This makes it possible to retain intact the specific properties of this fluoropolymer, namely its very good resistance to bad weather, to UV radiation and to visible light, and to chemicals.

The film can also be manufactured by cast film extrusion; this process consists in drawing, in air, a sheet or a film of polymer between a fiat die and a thermostatically controlled roll, It makes it possible to manufacture sheets with a thickness of between 0.2 mm and 2 mm and films with a thickness of less than 0.2 mm.

Another method employed to manufacture the film according to the invention is the solvent casting process. This is a process where pigments and a polymer are placed in solution. This solution, which comprises the dissolved polymer and the dispersed pigments, is subsequently deposited on a support. The solvent is subsequently evaporated under vacuum and by heating in order to make possible the formation of the film comprising the pigments. The support is subsequently removed and the film wound off. The final thickness of the film depends on the thickness of the solution deposited and on its solids content.

According to another aspect, a subject-matter of the invention is the use of this film in the manufacture of the backsheet in a photovoltaic panel. To this end, according to one embodiment, the film according to the invention is first subjected, on both its faces, to a surface treatment of corona type. Subsequently, it is heat laminated on each side with a PET sheet coated beforehand with adhesive, One of the faces of the laminate thus obtained is subsequently pressed against a film of EVA type, the other face of the latter being adhesively bonded to a cleaned glass sheet. This structure can be used as backsheet in a photovoltaic cell.

The film according to the invention is opaque (low transmission of visible light and UV rays) and additionally protects against penetration with oxygen. The structure retains an attractive aesthetic appearance of the film (no yellowing over time) and an excellent flame resistance.

The fluoropolymer-based film according to the invention exhibits a good thermal resistance (low shrinkage in volume when it is subjected to high temperatures) and an excellent resistance to the solvents present in the glues and adhesives used in the construction of photovoltaic cells and more particularly of the back panel of the cells. This structure is thus perfectly well suited to protecting the back panel of photovoltaic cells (backsheet).

As a result of the simultaneous presence of two white pigments, namely ZnO and TiO₂, the film according to the invention is opaque to UV radiation (up to 395 nm) and only very slightly transparent in the visible region (the transmission is less than 25% at 450 nm), for a film with a thickness of less than 20 μm and exhibiting a density of less than 2100 kg/m³, The film obtained also exhibits a yellowing index of less than 4.

A better understanding of the present invention will be obtained in the light of the implementational examples which will follow.

Measurement of the Mechanical Properties

The elongation at break and the tensile strength in the two directions of the film were measured according to Standard EN 06074-2.

Dimensional Stability Test

The shrinkage of the film is measured according to Standard ISO 11501, A square piece of film with dimensions of 20 cm×20 cm is placed in a ventilated oven at 150° C. for 30 min. The dimensions are subsequently measured again. The shrinkage is then evaluated by the variation in each of the dimensions, with respect to the initial dimension.

UV Ageing test

The UV accelerated ageing test is carried out using a QUV tester, the following conditions being applied to the sample: 8 hours of QUV B 313 (UV-B lamps at 313 nm) at 60° C., 0.89 W/m²/nm, then 4 hours at 45° C., with condensation of water on the sample. This test is carried for 2000 h.

Damp Heat Test

The test is carried out in a climate-controlled chamber where a temperature of 85° C. and a humidity of 85% are maintained. After 2000 h, the samples are withdrawn and analysed.

### EXAMPLE 1

### According to the Invention

Kynar 720 from Arkema (PVDF homopolymer, MFI of 20 at 230° C. under 5 kg, viscosity of 800 Pa·s at 230° C. under shearing of 100 s⁻¹) and zinc oxide (ZnO) with a D50 size of approximately 1 μm and with a density of 5.6 are blended at a temperature of less than 230° C. on a cokneader from Buss of PR 46 type (speed of the cokneader 200 rev/minute and speed of the take-up screw 60 rev/minute), The blend comprises 60% of Kynar 720 and 40% of zinc oxide. The blend thus produced (masterbatch A) does not exhibit any sign of decomposition after this extrusion stage.

This masterbatch A is blended in a Buss cokneader at 230° C. (speed of the cokneader 200 rev/minute and speed of the take-up screw 60 rev/minute) with another homopolymer from Arkema, Kynar 740 (WI of 3 at 230° C. under 10 kg, viscosity of 2000 Pa·s at 230° C. under 100 s⁻¹), and with an acrylic masterbatch (the masterbatch B, composed of 40% of PMMA BS550 from Arkema and of 60% of TiO₂ of R960 type). The blend thus produced comprises 54.2% of Kynar 740, 8.3% of masterbatch B and 37.5% of masterbatch A. Its composition by weight is as follows; 15% ZnO, 4.98% TiO₂ and 3.32% acrylic.

The product thus obtained is subsequently extruded on a blown film extrusion line from Dr Collin GmbH, Ebersberg, Germany. The extrusion temperature is 240° C. and the blow ratio is 2.5. The film produced exhibits a width of 250 mm and a thickness of 18 μm and a density of 2.01. This film is completely opaque in the UV region up to 395 nm and exhibits a transmission of 22% at 450 nm. This film is subsequently laminated on a biaxially oriented PET with a thickness of 250 μm using an adhesive from Bostik, a mixture of HBTS EPS 877 and Boscodur 1621. A thickness of adhesive of 8 μm is used and the laminate is postcrosslinked at 60° C. for 60 h. After this stage of curing the adhesive, an adhesion of 8 N/cm is measured. The laminate obtained is subsequently placed in a climate-controlled chamber at 85° C. and 85% relative humidity. No delamination is obtained and no yellowing is observed after ageing for 2000 h. This same laminate, after a UV ageing test as described above, does not exhibit any yellowing.

### Example 2

### According to the Invention

Kynar 720 from Arkema (PVDF homopolymer, MFI of 20 at 230° C. under 5 kg, viscosity of 800 Pa·s at 230° C. under shearing of 100 s⁻¹) and zinc oxide (ZnO) with a D50 size of approximately 1 μm and with a density of 5.6 are blended at a temperature of less than 230° C. on a cokneader from Buss of PR 46 type (speed of the cokneader 200 rev/minute and speed of the take-up screw 60 rev/minute). The blend comprises 60% of Kynar 720 and 40% of zinc oxide. The blend thus produced (masterbatch A) does not exhibit any sign of decomposition after this extrusion stage.

This masterbatch A is blended in a Buss cokneader at 230° C. (speed of the cokneader 200 rev/minute and speed of the take-up screw 60 rev/minute) with another homopolymer from Arkema, Kynar 740 (MFI of 3 at 230° C. under 10 kg, viscosity of 2000 Pa·s at 230° C. under 100 s⁻¹), and with a masterbatch B, composed of 40% of PMMA BS550 from Arkema and of 60% of TiO₂ of R960 type. The blend thus produced comprises 50.8% of Kynar 740, 11.7% of masterbatch B and 37.5% of masterbatch A. Its composition by weight is as follows: 15% ZnO, 7.02% TiO₂ and 4.68% acrylic.

The product thus obtained is subsequently extruded on a blown film extrusion line from Dr Collin GmbH. The extrusion temperature is 240° C. and the blow ratio is 2.5. The film produced exhibits a width of 250 mm and a thickness of 18 pm and a density of 2.02. This film is completely opaque in the UV region up to 395 nm and exhibits a S transmission of 18% at 450 nm. This film is subsequently laminated on a biaxially oriented PET with a thickness of 250 μm using an adhesive from Bostik, a mixture of HBTS EPS 877 and Boscodur 1621. A thickness of adhesive of 8 μm is used and the laminate is postcrosslinked at 60° C. for 60 h. After this stage of curing the adhesive, an adhesion of 8 N/cm is measured. The laminate obtained is subsequently placed in a climate-controlled chamber at 85° C. and 85% relative humidity. After 2000 h, no delamination is obtained and no yellowing is observed. This same laminate, after a UV ageing test as described above, does not exhibit any yellowing.

### Example 3

### Comparative

Kynar 720 from Arkema (PVDF homopolymer, MFI of 20 at 230° C. under 5 kg, viscosity of 800 Pa·s at 230° C. under shearing of 100 s⁻¹) and zinc sulphide (ZnS) with a D50 size of approximately 1 μm and with a density of 4.09 are blended at a temperature of less than 230° C.′ on a cokneader from Buss of PR 46 type (speed of the cokneader 200 rev/minute and speed of the take-up screw 60 rev/minute). The blend comprises 60% of Kynar 720 and 40% of zinc. sulphide. The blend thus produced (masterbatch A′) does not exhibit any sign of decomposition after this extrusion stage.

This masterbatch A′ is blended in a Buss cokneader at 230° C. (speed of the cokneader 200 rev/minute and speed of the take-up screw 60 rev/minute) with another homopolymer from Arkema, Kynar 740 (MFI of 3 at 230° C. under 10 kg, viscosity of 2000 Pa·s at 230° C. under 100 s⁻¹). The blend thus produced comprises 50% of Kynar 740 and 50% of masterbatch A′. The product thus obtained is subsequently extruded on a blown film extrusion line from Dr Collin GmbH. The extrusion temperature is 240° C. and the blow ratio is 2.5. The film produced exhibits a width of 250 mm and a thickness of 18 μm and a density of 2.00. This film is completely opaque in the UV region up to 375 nm and exhibits a transmission of 18% at 450 nm. This film is subsequently laminated on a biaxially oriented PET with a thickness of 250 μm using an adhesive from Bostik, a mixture of HBTS EPS 877 and Boscodur 1621. A thickness of adhesive of 8 pm is used and the laminate is postcrosslinked at 60° C. for 60 hr. After this stage of curing the adhesive, an adhesion of 8 N/cm is measured. The laminate obtained is subsequently placed in a climate-controlled chamber at 85° C. and 85% relative humidity. After 2000 h, no delamination is obtained and no yellowing is observed. This same laminate, after a UV ageing test as described above, has completely lost it opaqueness in the visible and UV regions and a strong yellowing is observed.

1. A composition comprising at least one fluoropolymer and of two white inorganic fillers, wherein said fillers are zinc oxide and titanium oxide, in that they are present in a proportion by weight ranging from 5 to 30% and from 3 to 7.5% respectively, and wherein said composition additionally comprises at least one acrylic polymer at up to 5% by weight, with respect to the total weight of the composition.

2. The composition according to claim 1, wherein said at least one fluoropolymer is selected from the group consisting of vinylidene fluoride homopolymers and copolymers of vinylidene fluoride with at least one other fluoromonomer.

3. The composition according to claim 1, wherein there are two distinct fluoropolymers, at least one of which is a vinylidene fluoride homopolymer.

4. The composition according to claim 1, wherein the content by weight of zinc oxide ranges from 10 to 20% by weight.

5. The composition according to claim 1, wherein the content by weight of titanium oxide ranges from 3 to 6% by weight.

6. The composition according to claim 1, wherein the said acrylic polymer is a methyl methacrylate homopolymer or a copolymer comprising at least 50% by weight of methyl methacrylate with least one other monomer which can copolymerize with methyl methacrylate selected from the group consisting of alkyl(meth)acrylates, acrylonitrile, butadiene, styrene and isoprene,

7. A monolayer film consisting of the composition according to claim 1, having a thickness of less than 20 microns.

8. The film according to claim 7, exhibiting an opaqueness to UV radiation and a transparency of less than 25% at 450 nm.

9. The film according to claim 7, exhibiting a long-term stability, as shown by the damp heat test at 85° C. and 85% humidity for 2000 h and by the QUV ageing test.

10. A photovoltaic panel, comprising the a backsheet a comprising said film according to claim 7 protecting the back panel.

11. (canceled)

12. A process for the preparation of the composition of claim 1, the said process comprises the following stages steps:
i) incorporating the molten state zinc oxide in a fluoropolymer having a viscosity of less than 1000 Pa·s at 230° C. for a shearing of 100 s⁻¹, in order to obtain a masterbatch A;
ii) incorporating in the molten state titanium oxide in an acrylic matrix, the TiO₂ content of this blend being greater than 50% by weight, in order to obtain a masterbatch B, and
iii) dispersing said masterbatch A in a more viscous fluorinated matrix than that of stage i), the masterbatch B being added to this blend.

13. The process for the manufacture of the monolayer film according to claim 7 comprising the step of blown film extrusion at a temperature ranging from 220 to 260° C.

14. The process for the manufacture of the monolayer film according to claim 7 comprising the step of east film extrusion.

15. The process for the manufacture of the monolayer film according to claim 7 comprising the step of solvent casting.

16. The monolayer film of claim 7 having a thickness between 15 and 19 microns.

17. The monolayer film of claim 16 having a thickness between 16 and 18 microns.
